(19) United States
(12) Patent Application Publication
(10) Pub. No.: US 2025/0107298 A1
(43) Pub. Date: Mar. 27, 2025

(54) PACKAGE STRUCTURE

(71) Applicant: Advanced Semiconductor Engineering, Inc., Kaohsiung (TW)

(72) Inventor: Hsin-Ying HO, Kaohsiung (TW)

(73) Assignee: Advanced Semiconductor Engineering, Inc., Kaohsiung (TW)

(21) Appl. No.: 18/373,853

(22) Filed: Sep. 27, 2023

(51) Int. Cl. H01L 33/62; H01L 23/00; H01L 25/075; H01L 25/16; H01L 33/54

(52) U.S. Cl. CPC H10H 20/857; H01L 24/29; H01L 24/32; H01L 24/45; H01L 24/48; H01L 24/73; H01L 25/0753; H01L 25/167; H10H 20/853; H01L 24/05; H01L 24/06; H01L 24/83; H01L 2224/05624; H01L 2224/05639; H01L 2224/05644; H01L 2224/05647; H01L 2224/06181; H01L 2224/2929; H01L 2224/29324; H01L 2224/29339; H01L 2224/29344; H01L 2224/29347; H01L 2224/32059; H01L 2224/32145; H01L 2224/32227; H01L 2224/45124; H01L 2224/45139; H01L 2224/45144; H01L 2224/45147; H01L 2224/48091; H01L 2224/48108; H01L 2224/48153; H01L 2224/48465; H01L 2224/48471; H01L 2224/73265; H01L 2224/83192; H01L 2224/83424; H01L 2224/83439; H01L 2224/83444; H01L 2224/83447; H01L 2224/83851; H01L 2224/83862; H01L 2924/0665; H01L 2924/12041; H01L 2924/20105

(57) ABSTRACT

A package structure is provided. The package structure includes a substrate, a first electronic component, an interposer, a conductive wire, and a conductive adhesive. The first electronic component and the interposer are disposed over the substrate. The conductive wire connects the first electronic component to the interposer. The conductive adhesive (connects the interposer to the substrate.

### BACKGROUND

### 1. Technical Field

The present disclosure relates generally to a package structure.

### 2. Description of the Related Art

Light-emitting elements that emit lights with different colors may be arranged in an array to collectively emit a white light. However, when a pitch of the array is designed to be relatively small to improve optical efficiency, conductive pastes that connect the light-emitting elements to a substrate may soften and overflow to undesirably cover adjacent conductive pads of the substrate during manufacture. As a result, conductive wires may fail to bond the light-emitting elements to the conductive pads of the substrate.

### SUMMARY

In one or more arrangements, a package structure includes a substrate, a first electronic component, an interposer, a conductive wire, and a conductive adhesive. The first electronic component and the interposer are disposed over the substrate. The conductive wire connects the first electronic component to the interposer. The conductive adhesive (connects the interposer to the substrate.

In one or more arrangements, a package structure includes a substrate, a first electronic component, a second electronic component, a conductive wire, a first conductive adhesive, and a second conductive adhesive. The first electronic component is disposed over the substrate. The first electronic component has a first surface facing the substrate and a second surface opposite to the first surface. The second electronic component is disposed over the substrate. The second electronic component has a third surface facing the substrate and including a first electrode on the third surface. The conductive wire electrically connects the second surface to the substrate (10). The first conductive adhesive connects the first surface to the substrate. The second conductive adhesive connects the first electrode on the third surface to the substrate.

In one or more arrangements, a package structure includes a substrate, a light-emitting array, and a plurality of interposers. The light-emitting array is disposed over the substrate. The light-emitting array includes a plurality of first light-emitting elements flip-chip bonded to the substrate and a plurality of second light-emitting elements wire-bonded to the substrate. The interposers are disposed over the substrate. The second light-emitting elements are wire-bonded to the substrate through the interposers.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a top view of a package structure in accordance with some arrangements of the present disclosure.

FIG. 1B is a cross-section of a package structure in accordance with some arrangements of the present disclosure.

FIG. 2A is a cross-section of a portion of a package structure in accordance with some arrangements of the present disclosure.

FIG. 2B is a cross-section of a portion of a package structure in accordance with some arrangements of the present disclosure.

FIG. 2C is a cross-section of a portion of a package structure in accordance with some arrangements of the present disclosure.

FIG. 2D is a top view of a portion of a package structure in accordance with some arrangements of the present disclosure.

FIG. 3 is a cross-section of a package structure in accordance with some arrangements of the present disclosure.

FIG. 4A is a cross-section of a portion of a package structure in accordance with some arrangements of the present disclosure.

FIG. 4B is a cross-section of a portion of a package structure in accordance with some arrangements of the present disclosure.

FIG. 4C is a cross-section of a portion of a package structure in accordance with some arrangements of the present disclosure.

FIG. 5 is a cross-section of a package structure in accordance with some arrangements of the present disclosure.

FIG. 6A, FIG. 6B, and FIG. 6C illustrate various stages of an exemplary method for manufacturing a package structure in accordance with some arrangements of the present disclosure.

Common reference numerals are used throughout the drawings and the detailed description to indicate the same or similar elements.

### DETAILED DESCRIPTION

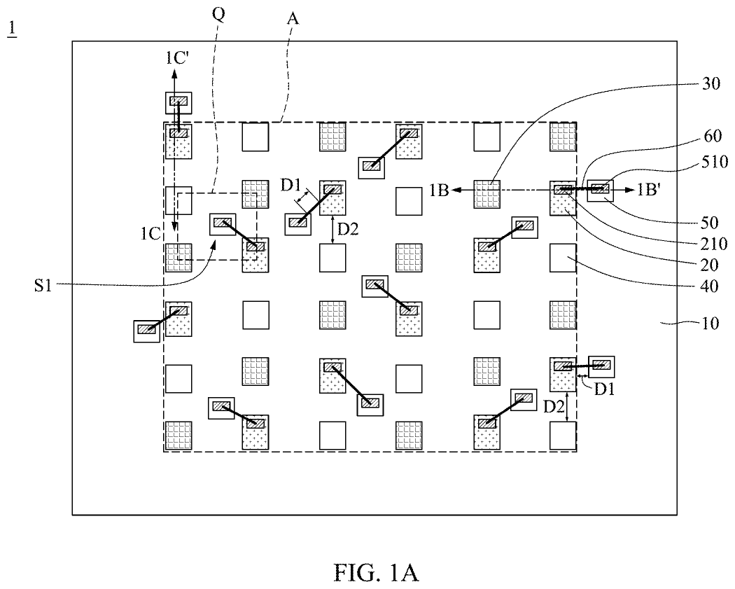

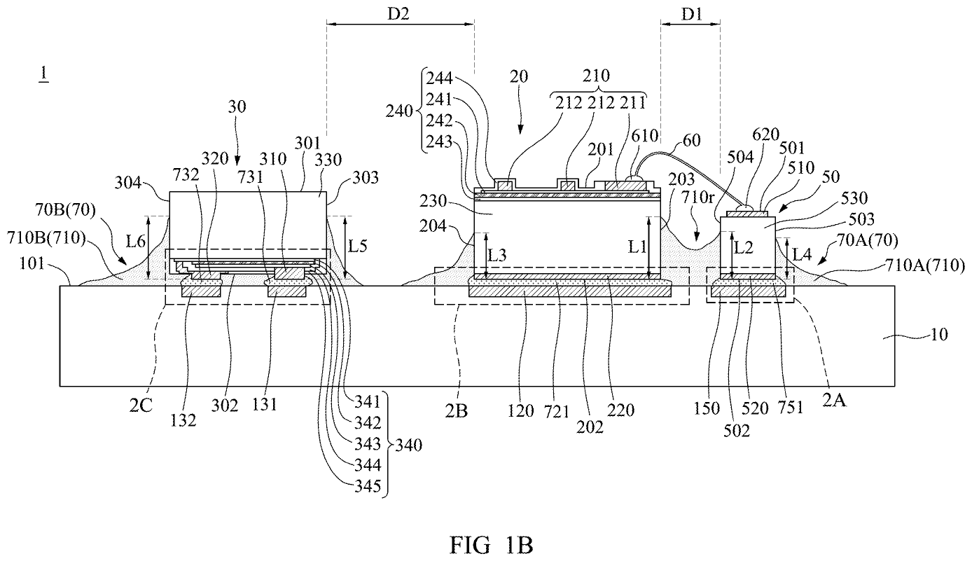

FIG. 1A is a top view of a package structure 1 in accordance with some arrangements of the present disclosure. The package structure 1 may include a substrate 10, an array including electronic components 20, 30, and 40, interposers 50, and conductive wires 60.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, which may include such as a plurality of conductive traces and/or a plurality of conductive vias. The interconnection structure may include a redistribution layer (RDL) and/or a grounding element. In some arrangements, the substrate 10 may include an organic substrate or a leadframe. In some arrangements, the substrate 10 may include a ceramic material or a metal plate. In some arrangements, the substrate 10 may include a two-layer substrate which includes a core layer and a conductive material and/or structure disposed on an upper surface and a bottom surface of the substrate. The substrate 10 may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The substrate 10 may include one or more conductive elements, surfaces, contacts, or pads.

The array (e.g., the electronic components 20, 30, and 40) may be disposed over the substrate 10. The array may be or include a light-emitting array. The package structure 1 including the light-emitting array may function as a light source. The package structure 1 may be installed or disposed into an optical engine (e.g., a light engine). The electronic components 20, 30, and 40 may be or include light-emitting elements (e.g., light-emitting diodes) configured to emit lights with different colors. For example, the electronic component 20 may be or include a red light-emitting element, the electronic component 30 may be or include a green light-emitting element, and the electronic component 40 may be or include a blue light-emitting element. The electronic components 20, 30, and 40 may collectively emit a white light. In some arrangements, the electronic components 20 are wire-bonded to the substrate 10. In some arrangements, the electronic components 30 and 40 are flip-chip bonded to the substrate 10. For example, each of the electronic components 30 and 40 has two electrodes facing and bonded to the substrate 10 (or the conductive pads of the substrate 10). The arrangements and the numbers of the electronic components 20, 30, and 40 may vary according to actual applications and are not limited thereto.

The interposers 50 and the conductive wires 60 may be disposed over the substrate 10. In some arrangements, the interposers 50 are electrically connected to the substrate 10, and the conductive wires 60 are electrically connected to the interposers 50. In some arrangements, the electronic components 20 are wire-bonded to the substrate 10 through the interposers 50 and the conductive wires 60. In some arrangements, a terminal 210 (e.g. a conductive pad) of the electronic component 20 is electrically connected to a conductive pad 510 of the interposer 50 through the conductive wire 60, and then the conductive pad 510 is electrically connected to the substrate 10 through a conductive material of the interposer 50. In some arrangements, the interposer 50 is or includes a dummy die including a semiconductor substrate or a doped substrate. The semiconductor substrate or the doped substrate may include the conductive material.

In some arrangements, one or more of the interposers 50 may be interposed in one or more spaces between any two or more adjacent electronic components 20, 30, and/or 40 from a top view perspective. In some arrangements, one of the interposers 50 connected to one of the electronic components 20 is disposed between the one of the electronic components 20 and one of the electronic components 30 adjacent to the one of the electronic components 20 from a top view perspective. The one of the electronic components 20 is closer to the one of the interposers 50 than to the one of the electronic components 30. In some arrangements, at least one of the interposers 50 is interposed in a space S1 adjacent to a diagonal intersection of a virtual quadrangle Q defined by the electronic components 20, 30, and/or 40 from a top view perspective. In some arrangements, at least one of the interposers 50 is disposed outside of a coverage area A of the light-emitting array from a top view perspective. In some arrangements, each of the interposers 50 is wire-bonded to each of the electronic components 20 and separated from each other by a distance D1, and the distance D1 is smaller than a minimum distance D2 between any two of the electronic components 20, 30, and 40. The distance D2 may be referred to a pitch of the array of the electronic components 20, 30, and 40. According to some arrangements of the present disclosure, the relatively small pitch of the array (or the light-emitting array) can provide a relatively satisfactory mixing of lights, such that a white light with a relatively good quality and intensity can be provided. In some arrangements, the distance D2 (or the pitch) may be less than about 300 μm. In some arrangements, the distance D2 (or the pitch) may be from about 50 μm to about 280 μm.

FIG. 1B is a cross-section of a package structure 1 in accordance with some arrangements of the present disclosure. In some arrangements, FIG. 1B is a cross-section along a cross-sectional line 1B-1B′ in FIG. 1A. In some arrangements, the package structure 1 may include a substrate 10, an array including electronic components 20, 30, and 40, interposers 50, conductive wires 60, and a conductive adhesive 70.

In some arrangements, the substrate 10 includes conductive pads 120, 131, 132, and 150. In some arrangements, the conductive pads 120, 131, 132, and 150 are exposed by a surface 101 of the substrate 10. In some arrangements, the substrate 10 includes a dielectric layer, and surfaces of the conductive pads 120, 131, 132, and 150 are exposed by the dielectric layer. The conductive pads 120, 131, 132, and 150 may be electrically connected to an interconnection structure (e.g., a RDL) of the substrate 10. In some arrangements, the conductive pads 120, 131, 132, and 150 may independently include a conductive material such as a metal or metal alloy. Examples include gold (Au), silver (Ag), aluminum (Al), copper (Cu), or an alloy thereof. The dielectric layer may include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

The electronic component 20 may be disposed over the substrate 10. The electronic component 20 may have a surface 201 (or an upper surface or a top surface), a surface 202 (or a lower surface or a bottom surface) opposite to the surface 201, and surfaces 203 and 204 (or lateral surfaces or lateral sidewalls). The surface 202 may face the substrate 10. In some arrangements, the electronic component 20 includes terminals 210 and 220 (also referred to as “conductive pads” or “electrodes”), a substrate 230, and a light-emitting layer 240 (also referred to as “a light-emitting source”). In some arrangements, the terminal 210 is electrically connected to the interposer 50 through the conductive wire 60, and the terminal 220 is electrically connected to the conductive pad 120 of the substrate 10.

In some arrangements, the terminals 210 and 220 may include conductive terminals, conductive pads, conductive patterns, or the like. In some arrangements, the terminal 210 and the terminal 220 are on opposite sides of the electronic component 20. For example, the terminal 210 is exposed by the surface 201, and the terminal 220 is exposed by the surface 202. In some arrangements, the terminal 210 includes a patterned conductive layer having a contact portion 211 and patterned portions 212 (also referred to as “conductive fingers”). The terminals 210 and 220 may independently include a conductive material such as a metal or metal alloy. Examples include Au, Ag, Al, Cu, or an alloy thereof. In some arrangements, the electronic component 20 is a light-emitting element, and the terminals 210 and 220 are the electrodes of the light-emitting element.

In some arrangements, the substrate 230 may be or include a semiconductor substrate. The substrate 230 may be or include a sapphire substrate or a compound semiconductor substrate. In some arrangements, the terminals 210 and 220 (or the electrodes) are on opposite sides of the light-emitting layer 240. In some arrangements, the light-emitting layer 240 includes a first-type semiconductor layer 241, a second-type semiconductor layer 242, a reflective layer 243, and a passivation layer 244. The first-type semiconductor layer 241 may include one of an n-type layer and a p-type layer, and the second-type semiconductor layer 242 may include another one of an n-type layer and a p-type layer. The first-type semiconductor layer 241 and the second-type semiconductor layer 242 may collectively emit a light with a predetermined color. The first-type semiconductor layer 241 may connect to or contact the terminal 210. The reflective layer 243 may include a reflective metal. The reflective layer 243 is configured to reflect the light emitted from the interface between the first-type semiconductor layer 241 and the second-type semiconductor layer 242 to guide the light to emit from or out of the surface 201 of the electronic component 20. The passivation layer 244 may include a dielectric layer.

The electronic component 30 may be disposed over the substrate 10. The electronic component 30 may have a surface 301 (or an upper surface), a surface 302 (or a lower surface) opposite to the surface 301, and surfaces 303 and 304 (or lateral surfaces or lateral sidewalls). The surface 302 may face the substrate 10. In some arrangements, the electronic component 30 includes terminals 310 and 320 (also referred to as “conductive pads” or “electrodes”), a substrate 330, and a light-emitting layer 340 (also referred to as “a light-emitting source”). The terminals 310 and 320 (or the electrodes) are on the surface 302 of the electronic component 30. The electronic component 30 may be flip-chip bonded to the substrate 10 through the terminals 310 and 320 (also referred to as “electrodes”). In some arrangements, the electronic component 30 is flip-chip bonded to the substrate 10 by the terminals 310 and 320 both facing the substrate 10 and electrically connected to the substrate 10. In some arrangements, the terminal 310 is electrically connected to the conductive pad 131 of the substrate 10, and the terminal 320 is electrically connected to the conductive pad 132 of the substrate 10.

In some arrangements, the terminals 310 and 320 may include conductive terminals, conductive pads, conductive patterns, or the like. In some arrangements, the terminals 310 and 320 are on the same side of the electronic component 30. For example, the terminals 310 and 320 are exposed by the surface 302. The terminals 310 and 320 may independently include a conductive material such as a metal or metal alloy. Examples include Au, Ag, Al, Cu, or an alloy thereof. In some arrangements, the electronic component 30 is a light-emitting element, and the terminals 310 and 320 are the electrodes of the light-emitting element.

In some arrangements, the substrate 330 may be or include a semiconductor substrate. The substrate 330 may be or include a sapphire substrate or a compound semiconductor substrate. In some arrangements, an elevation of the light-emitting layer 340 (or the light-emitting source) of one of the electronic components 30 (or the light-emitting elements) is lower than an elevation of the light-emitting layer 240 (or the light-emitting source) of one of the electronic components 20 (or the light-emitting elements) with respect to the substrate 10. In some arrangements, the terminals 310 and 320 (or the electrodes) are on a same side of the light-emitting layer 340. In some arrangements, the light-emitting layer 340 includes a first-type semiconductor layer 341, a second-type semiconductor layer 342, a reflective layer 343, and passivation layers 344 and 345. The first-type semiconductor layer 341 may include one of an n-type layer and a p-type layer, and the second-type semiconductor layer 342 may include another one of an n-type layer and a p-type layer. The first-type semiconductor layer 341 and the second-type semiconductor layer 342 may collectively emit a light with a predetermined color. The light-emitting layer 340 may be connected to the terminals 310 and 320. In some arrangements, the terminal 310 may be connected to the second-type semiconductor layer 342, and the terminal 320 may be connected to the first-type semiconductor layer 341. The reflective layer 343 may include a reflective metal. The reflective layer 343 is configured to reflect the light emitted from the interface between the first-type semiconductor layer 341 and the second-type semiconductor layer 342 to guide the light to emit from or out of the surface 301 of the electronic component 30. The passivation layers 344 and 345 may include dielectric layers.

The interposers 50 may be disposed over the substrate 10. The interposer 50 may have a surface 501 (or an upper surface), a surface 502 (or a lower surface), and surfaces 503 and 504 (or lateral surfaces or lateral sidewalls). The interposer 50 may electrically connect the conductive wire 60 to the substrate 10. In some arrangements, the interposer 50 includes conductive pads 510 and 520 and a substrate 530. The conductive pad 510 may be connected to the conductive wire 60. The conductive pad 510 may be adjacent to the surface 501 and electrically connected to the terminal 210 through the conductive wire 60. The conductive pad 510 may be at an elevation higher than that of the conductive pad 150 with respect to the surface 101. In some arrangements, the conductive pad 510 is exposed to a space outside of the package structure 1. In some arrangements, the conductive pad 510 is exposed to an air space. The surface 501 may be at an elevation higher than that of the conductive pad 150 with respect to the surface 101. The interposer 50 may be flip-chip bonded to the substrate 10 through the conductive pad 520. In some arrangements, the conductive pad 520 is electrically connected to the conductive pad 150 of the substrate 10. In some arrangements, a height of the electronic component 20 is greater than a height of the interposer 50. In some arrangements, the interposer 50 includes a conductive material. In some arrangements, the interposer 50 includes a doped semiconductor substrate (e.g., the substrate 530). In some arrangements, the interposer 50 does not include any metal pillar. In some arrangements, the interposer 50 is or includes a dummy die.

In some arrangements, the conductive wire 60 connects or electrically connects the electronic component 20 (e.g., the terminal 210) to the interposer 50. In some arrangements, the conductive wire 60 electrically connects the surface 202 of the electronic component 20 to the substrate 10. In some arrangements, the conductive wire 60 is spaced apart from the substrate 10 by the interposer 50. In some arrangements, the conductive wire 60 is exposed to a space outside of the package structure 1. In some arrangements, the conductive wire 60 is exposed to an air space. In some arrangements, the conductive wire 60 further includes a contact 610 connecting to the terminal 210 and a contact 620 connecting to the conductive pad 510. In some arrangements, the contact 610 is a ball bond, and the contact 620 is a stitch bond. In some arrangements, the contact 610 may be a stitch bond, and the contact 620 may be a ball bond, such that the loop height of the conductive wire 60 may be reduced. In some arrangements, an elevation of the contact (e.g., the contact 610) between the conductive wire 60 and the electronic component 20 is higher than an elevation of a contact (e.g., the contact 620) between the conductive wire 60 and the interposer 50 with respect to the substrate 10. The conductive wire 60 may include a conductive material, e.g., Au, Ag, Al, Cu, or an alloy thereof.

The conductive adhesive 70 may be disposed over the substrate 10. In some arrangements, the conductive adhesive 70 connects the interposer 50 to the substrate 10. In some arrangements, the electronic components 20 and 30 and the interposer 50 are electrically connected to the substrate 10 through the conductive adhesive 70. In some arrangements, the conductive adhesive 70 partially covers the electronic components 20 and 30 and the interposers 50. The conductive pad 510 may be at least partially exposed by the conductive adhesive 70. In some arrangements, the conductive wire 60 is exposed by the conductive adhesive 70. In some arrangements, the conductive adhesive 70 includes a portion 70A (also referred to as “a first conductive adhesive”) connecting the surface 202 of the electronic component 20 to the substrate 10. In some arrangements, the portion 70A is between the interposer 50 and the substrate 10 and connected to the interposer 50 and the substrate 10. In some arrangements, the conductive adhesive 70 further includes a portion 70B (also referred to as “a second conductive adhesive”) connecting the terminal on the surface 302 (e.g., the terminals 310 and 320) of the electronic component 30 to the substrate 10. The portion 70A may be spaced apart from the portion 70B. The conductive adhesive 70 may be or include an anisotropic conductive adhesive (ACF). The conductive adhesive 70 may be or include a self-assembly paste (SAP).

In some arrangements, the conductive adhesive 70 includes a resin structure 710 and a plurality of conductive portions (e.g., conductive portions 721, 731, 732, and 751). The resin structure 710 may be or include an insulating structure. The resin structure 710 may be referred to as a protective structure or a protective element for the conductive portions. In some arrangements, the resin structure 710 partially covers the electronic components 20 and 30 and the interposers 50. In some arrangements, the resin structure 710 includes a resin portion 710A contacting the electronic component 20 and the interposer 50 and a resin portion 710B contacting the electronic component 30. A portion of the surface 101 may be exposed by a gap between the resin portions 710A and 710B. The resin portion 710A and 710B may be or include insulating structures. In some arrangements, the resin structure 710 covers the conductive portions 721, 731, 732, and 751. The conductive portions 721, 731, 732, and 751 may be referred to as self-assembly pastes (SAPs). In some arrangements, the conductive portions 721, 731, 732, and 751 are spaced apart from one another by the resin structure 710. In some arrangements, one or more of the conductive portions (e.g., the conductive portions 721, 731, 732, and 751) of the conductive adhesive 70 may directly contact one or more of the conductive pads (e.g., the conductive pads 120, 131, 132, and 150) of the substrate 10. The resin structure 710 may include an epoxy-based resin. The conductive portions 721, 731, 732, and 751 may include Au, Ag, Al, Cu, or an alloy thereof.

In some arrangements, the conductive adhesive 70 is formed from an ACF material including a resin and a plurality of conductive particles dispersed in the resin. As the ACF material is heated and optionally pressed, the conductive particles may diffuse toward one or more conductive features and aggregate (or self-assemble) into conductive portions (e.g., the conductive portions 721, 731, 732, and 751), and the resin with less or nearly no conductive particles forms the resin structure 710. With such properties, the conductive portions 721, 731, 732, and 751 may be formed to contact conductive features, and the resin structure 710 may cover and directly contact the conductive portions 721, 731, 732, and 751.

In some arrangements, the conductive adhesive 70 electrically connects the interposer 50 to the substrate 10 and partially covers the interposer 50. In some arrangements, the conductive pad 510 of the interposer 50 contacts the conductive wire 60 and is at least partially exposed by the conductive adhesive 70. In some arrangements, the conductive pad 510 of the interposer 50 is exposed by the resin structure 710. In some arrangements, the conductive adhesive 70 is free from horizontally overlapping the conductive pad 510. In some arrangements, the conductive adhesive 70 horizontally overlaps the conductive pad 520. In some arrangements, the resin structure 710 horizontally overlaps the conductive pad 520. In some arrangements, the conductive pad 520 of the interposer 50 is electrically connected to the conductive pad 150 of the substrate 10 through the conductive adhesive 70. In some arrangements, the conductive pad 520 is electrically connected to the conductive pad 150 through the conductive portion 751 of the conductive adhesive 70. In some arrangements, the conductive portion 751 directly contacts the conductive pad 520 and the conductive pad 150. In some arrangements, the conductive portion 751 is spaced apart from the conductive pad 510 vertically.

In some arrangements, the conductive adhesive 70 electrically connects the electronic component 20 to the substrate 10 and partially covers the electronic component 20. In some arrangements, the terminal 210 of the electronic component 20 contacts the conductive wire 60 and is at least partially exposed by the conductive adhesive 70. In some arrangements, the terminal 210 is exposed by the resin structure 710. In some arrangements, the conductive adhesive 70 is free from horizontally overlapping the terminal 210. In some arrangements, the conductive adhesive 70 horizontally overlaps the terminal 220. In some arrangements, the resin structure 710 horizontally overlaps the terminal 220. In some arrangements, the terminal 220 of the electronic component 20 is electrically connected to the conductive pad 120 of the substrate 10 through the conductive adhesive 70. In some arrangements, the terminal 220 of the electronic component 20 is electrically connected to the conductive pad 120 through the conductive portion 721 of the conductive adhesive 70. In some arrangements, the conductive portion 721 directly contacts the terminal 220 and the conductive pad 120. In some arrangements, the conductive portion 721 is spaced apart from the terminal 210 vertically.

In some arrangements, the conductive adhesive 70 electrically connects the electronic component 30 to the substrate 10 and partially covers the electronic component 30. In some arrangements, a portion of the conductive adhesive 70 flip-chip bonds the electronic component 30 to the substrate 10. In some arrangements, the terminals 310 and 320 of the electronic component 30 are electrically connected to the substrate 10 through the conductive adhesive 70. In some arrangements, the terminals 310 and 320 of the electronic component 30 are electrically connected to the conductive pads 131 and 132 through the conductive portion 731 and 732 of the conductive adhesive 70. In some arrangements, the conductive portion 731 directly contacts the terminal 310 and the conductive pad 131, and the conductive portion 732 directly contacts the terminal 320 and the conductive pad 132. In some arrangements, the conductive adhesive 70 horizontally overlaps the terminals 310 and 320. In some arrangements, the resin structure 710 horizontally overlaps the terminals 310 and 320. In some arrangements, the conductive adhesive 70 horizontally overlaps the light-emitting layer 340. In some arrangements, the resin structure 710 horizontally overlaps the light-emitting layer 340.

In some arrangements, the conductive adhesive 70 extends continuously from the surface 203 (or the lateral sidewall) of the electronic component 20 to the surface 504 (or the lateral sidewall) of the interposer 50 in a cross-sectional view perspective. In some arrangements, the resin structure 710 extends over the surface 203 (or the lateral surface) of the electronic component 20 by a length L1 and extends over the surface 504 (or the lateral surface) of the interposer 50 by a length L2 different from the length L1. In some arrangements, the length L2 is less than the length L1. In some arrangements, the resin structure 710 extends over the surface 204 (or the lateral surface) of the electronic component 20 by a length L3 less than the length L1. In some arrangements, the resin structure 710 extends over the surface 503 (or the lateral surface) of the interposer 50 by a length L4 less than the length L2. In some arrangements, the resin structure 710 has a recess 710r between the electronic component 20 and the interposer 50. In some arrangements, the lengths L1 and L3 may be at least a half of the height (or the thickness) of the electronic component 20. For example, a ratio of the length L1 (or the length L3) with respect to a height or a thickness of the electronic component 20 may be equal to or greater than 0.5. In some arrangements, the lengths L2 and L4 may be greater than a half of the height (or the thickness) of the interposer 50. For example, a ratio of the length L2 (or the length L4) with respect to a height or a thickness of the interposer 50 may be greater than 0.5. In some arrangements, the electronic component 20 and the interposer 50 are partially encapsulated or fixed by the same resin structure 710, and a height (or a thickness) of the interposer 50 is less than a height (or a thickness) of the electronic component 20, such that the ratio of the length L2 (or the length L4) with respect to the height of the interposer 50 is greater than the ratio of the length L1 (or the length L3) with respect to the height of the electronic component 20.

In some arrangements, the resin structure 710 extends over the surface 303 (or the lateral surface) of the electronic component 30 by a length L5 and extends over the surface 304 (or the lateral surface) of the electronic component 30 by a length L6 different from the length L5. In some arrangements, the lengths L5 and L6 are greater than the lengths L3 and L4. In some arrangements, the lengths L5 a For example, a ratio of the length L5 (or the length L6) with respect to a height or a thickness of the electronic component 30 may be equal to or greater than 0.5.nd L6 may be at least a half of the height (or the thickness) of the electronic component 30.

In some arrangements, referring to FIGS. 1A and 1B, the conductive adhesive 70 electrically connects the electronic components 20, 30, and 40 and the interposers 50 to the substrate 10. The electronic component 30 is taken as an example to describe the details of the structural arrangements of the substrate 10, the flip-chip bonded electronic components (e.g., the electronic components 30 and 40), and the conductive adhesive 70. In some arrangements, FIG. 1B may show a cross-section along a cross-sectional line 1C-1C′ in FIG. 1A by replacing the electronic component 30 by the electronic component 40. In the present arrangements, the electronic component 40 may have a structure similar to that of the electronic component 30 illustrated in FIG. 1B, and the cross-section of the structure along the cross-sectional line 1C-1C′ may be the same or similar to the cross-section of the structure along the cross-sectional line 1B-1B′ illustrated in FIG. 1B.

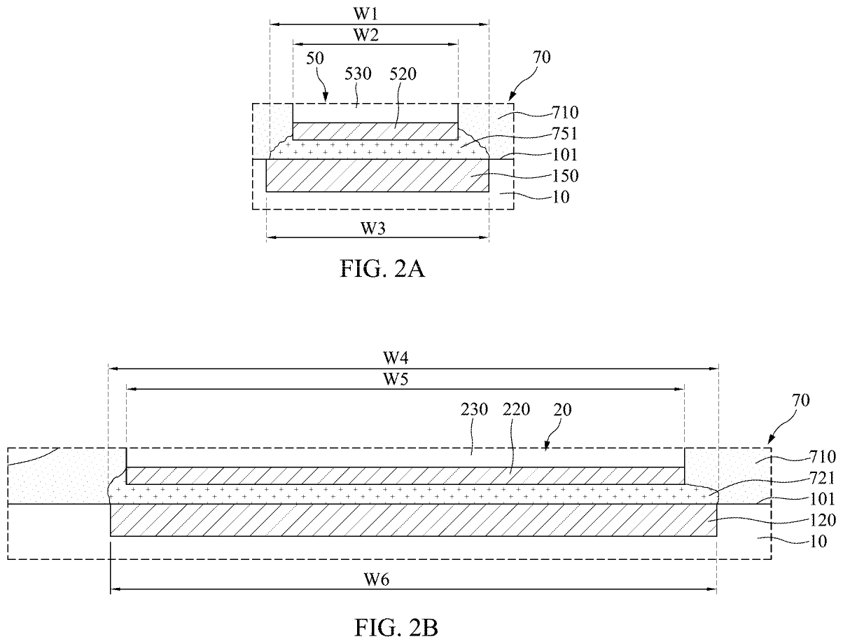

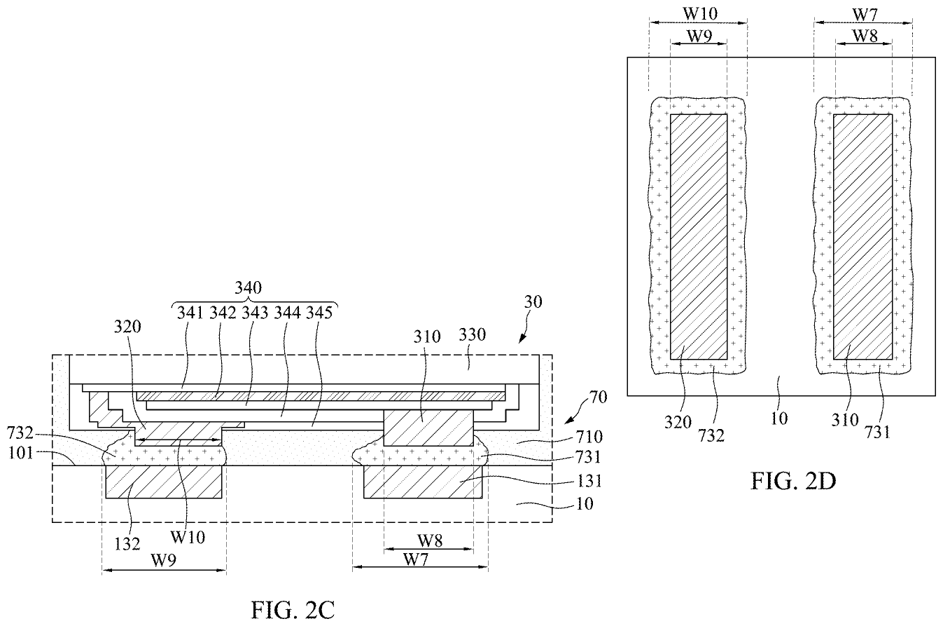

FIG. 2A is a cross-section of a portion of a package structure 1 in accordance with some arrangements of the present disclosure. In some arrangements, FIG. 2A is a cross-section of a portion 2A in FIG. 1B.

In some arrangements, an irregular interface is formed between the resin structure 710 and the conductive portion 751. In some arrangements, a width W1 of the conductive portion 751 is greater than a width W2 of the conductive pad 510 of the interposer 50. In some arrangements, the width W1 of the conductive portion 751 is substantially equal to or less than a width W3 of the conductive pad 150 of the substrate 10. The term “irregular interface” used herein may indicate a non-smooth surface or interface compared to a surface of a solder ball or an interface between a solder ball and a dielectric layer. For example, a soldering material may melt and form a solder ball having a relatively smooth surface resulted from the cohesion force of the solder ball during a reflow operation. An interface between a dielectric layer and the relatively smooth surface of a solder ball may be referred to as a “regular interface” as compared to the term “irregular interface” used herein.

In some arrangements, the conductive portion 751 covers or directly contacts the bottom surface of one or more portions of lateral surfaces of the conductive pad 510. In some arrangements, the conductive portion 751 is spaced apart from the substrate 530 of the interposer 50.

FIG. 2B is a cross-section of a portion of a package structure 1 in accordance with some arrangements of the present disclosure. In some arrangements, FIG. 2B is a cross-section of a portion 2B in FIG. 1B.

In some arrangements, an irregular interface is formed between the resin structure 710 and the conductive portion 721. In some arrangements, a width W4 of the conductive portion 721 is greater than a width W5 of the terminal 220 of the electronic component 20. In some arrangements, the width W4 of the conductive portion 721 is greater than a width W6 of the conductive pad 120 of the substrate 10. In some arrangements, the conductive portion 721 may extend or protrude beyond one or more lateral surfaces of the conductive pad 120.

In some arrangements, the conductive portion 721 covers or directly contacts the bottom surface of one or more portions of lateral surfaces of the terminal 220 of the electronic component 20. In some arrangements, the conductive portion 721 is spaced apart from the substrate 230 of the electronic component 20.

FIG. 2C is a cross-section of a portion of a package structure 1 in accordance with some arrangements of the present disclosure. In some arrangements, FIG. 2C is a cross-section of a portion 2C in FIG. 1B.

In some arrangements, an irregular interface is formed between the resin structure 710 and the conductive portion 731. In some arrangements, an irregular interface is formed between the resin structure 710 and the conductive portion 732. In some arrangements, a width W7 of the conductive portion 731 is greater than a width W8 of the terminal 310 of the electronic component 30. In some arrangements, a width W9 of the conductive portion 732 is greater than a width W10 of the terminal 320 of the electronic component 30. In some arrangements, the conductive portion 731 may extend or protrude beyond one or more lateral surfaces of the conductive pad 131. In some arrangements, the conductive portion 732 may extend or protrude beyond one or more lateral surfaces of the conductive pad 132.

In some arrangements, the conductive portion 731 covers or directly contacts the bottom surface of one or more portions of lateral surfaces of the terminal 310 of the electronic component 30. In some arrangements, the conductive portion 732 covers or directly contacts the bottom surface of one or more portions of lateral surfaces of the terminal 320 of the electronic component 30.

FIG. 2D is a top view of a portion of a package structure 1 in accordance with some arrangements of the present disclosure. In some arrangements, FIG. 2D is a top view of the terminals 310 and 320 and the conductive portions 731 and 732.

In some arrangements, the conductive portion 731 may extend or protrude beyond multiple lateral surfaces of the terminal 310. The conductive portion 731 may have an irregular peripheral shape, profile, or outline.

In some cases where an interposer is not arranged, an electronic component is electrically connected to a conductive pad of a substrate through a conductive paste, and a conductive wire connects a terminal of an electronic component to an adjacent conductive pad of the substrate. However, while a pitch or distance between the electronic component (or the conductive pad) and the adjacent conductive pad of the substrate is relatively small, the conductive paste may soften and overflow to undesirably cover the adjacent conductive pad of the substrate during manufacture, which prevents the conductive wire from bonding to the adjacent conductive pad of the substrate. In contrast, according to some arrangements of the present disclosure, an interposer is disposed over the substrate with a bonding surface between the interposer and the conductive wire at an elevation higher than that of a top surface of the conductive pad of the substrate, such that the bonding surface of the interposer can be prevented from being covered by the conductive adhesive (or the anisotropic conductive adhesive (ACF)) that connects the electronic component to the substrate, and thus the conductive wire can be bonded to the bonding surface of the interposer to electrically connect to the substrate.

In addition, in some cases wherein electronic components are bonded to a substrate through interposers (e.g., solders) followed by forming a protection layer (e.g., an underfill) to cover the interposers, such process requires multiple operations and various materials. In contrast, according to some arrangements of the present disclosure, the resin structure and the conductive portions of the ACF are formed from one ACF material instead of forming the conductive features and the insulating structure in two or more operations. Therefore, the manufacturing process is simplified, and the costs for the materials can be reduced.

Moreover, in some cases, metal pillars may be used to electrically connect a conductive wire to a substrate. However, the metal pillars are required to be formed on the substrate by a semiconductor manufacturing process, and the manufacture of the metal pillars has to be incorporated into the manufacturing process of the substrate. In contrast, according to some arrangements of the present disclosure, the interposer includes a doped semiconductor substrate or a dummy die, such that the interposer and the substrate can be manufactured separately and then bonded to each other, which reduces the processing steps and thus reduces the costs and time. In addition, the process for forming the interposer and the process for forming the electronic components are compatible, and thus the entire manufacturing process for the package structure can be simplified, such that the cost can be further reduced, and the yield can be increased.

Furthermore, according to some arrangements of the present disclosure, the conductive adhesive (or the resin structure) partially covers one or more lateral surfaces of one or more of the electronic components and the interposers to a predetermined range (e.g., over a half or higher of the height or thickness of the electronic component and/or the interposer), such that the connection interfaces or contact interfaces between the conductive adhesive and the components can be increased, the conductive adhesive can provide a sufficient support for the electronic components and the interposer, and thus the relative position can be fixed to an increased stability.

In addition, according to some arrangements of the present disclosure, the conductive portions of the conductive adhesive further cover or contact one or more lateral surfaces of the terminals and/or the conductive pads. Therefore, one or more areas of the electrical contact interfaces can be increased, and thus the electrical conduction is further improved.

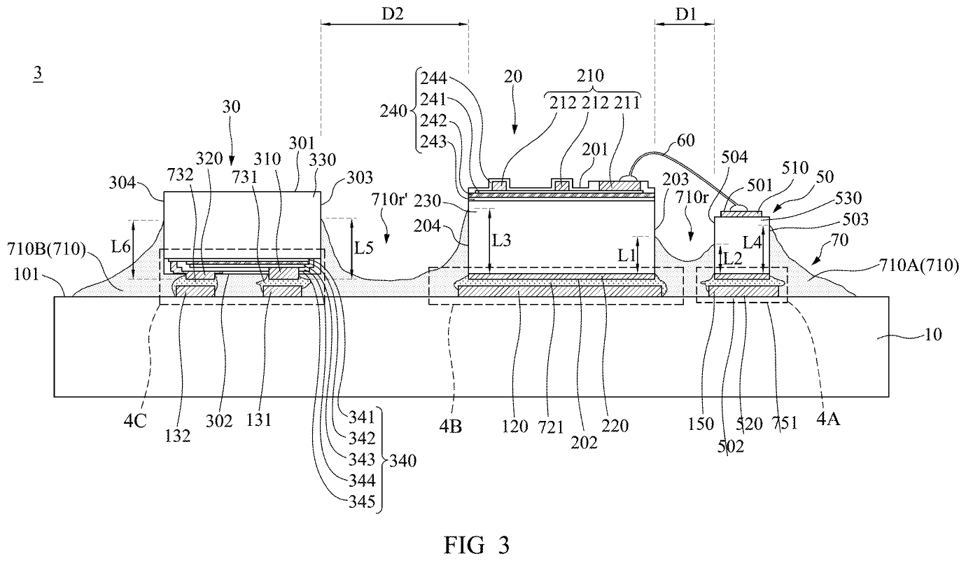

FIG. 3 is a cross-section of a package structure 3 in accordance with some arrangements of the present disclosure. In some arrangements, the package structure 1 illustrated in FIG. 1A may include a structure illustrated in FIG. 3. In some arrangements, FIG. 3 may illustrate a cross-section along the cross-sectional line 1B-1B′ in FIG. 1A. In some arrangements, the package structure 3 has a structure similar to the structure illustrated in FIG. 1B, with differences therebetween as follows.

In some arrangements, the resin structure 710 defines a recess 710r between the electronic component 20 and the interposer 50 and a recess 710r′ between the electronic component 20 and the electronic component 30. In some arrangements, the recess 710r and the recess 710r′ are at different elevations. In some arrangements, bottoms of the recess 710r and the recess 710r′ are at different elevations. In some arrangements, the recess 710r and the recess 710r′ have different depths. For example, the recess 710r between the interposer 50 and the electronic component 20 disposed closer to each other has a smaller depth, and the recess 710r′ between the electronic component 20 and the electronic component 30 disposed farther from each other has a greater depth.

In some arrangements, the resin structure 710 extends over the surface 203 (or the lateral surface) of the electronic component 20 by a length L1 and extends over the surface 504 (or the lateral surface) of the interposer 50 by a length L2 different from the length L1. In some arrangements, the length L2 is less than the length L1. In some arrangements, the resin structure 710 extends over the surface 204 (or the lateral surface) of the electronic component 20 by a length L3 greater than the length L1. In some arrangements, the resin structure 710 extends over the surface 503 (or the lateral surface) of the interposer 50 by a length L4 greater than the length L2. In some arrangements, the resin structure 710 extends over the surface 303 (or the lateral surface) of the electronic component 30 by a length L5 and extends over the surface 304 (or the lateral surface) of the electronic component 30 by a length L6 different from the length L5. In some arrangements, the length L3 is greater than the lengths L5 and L6.

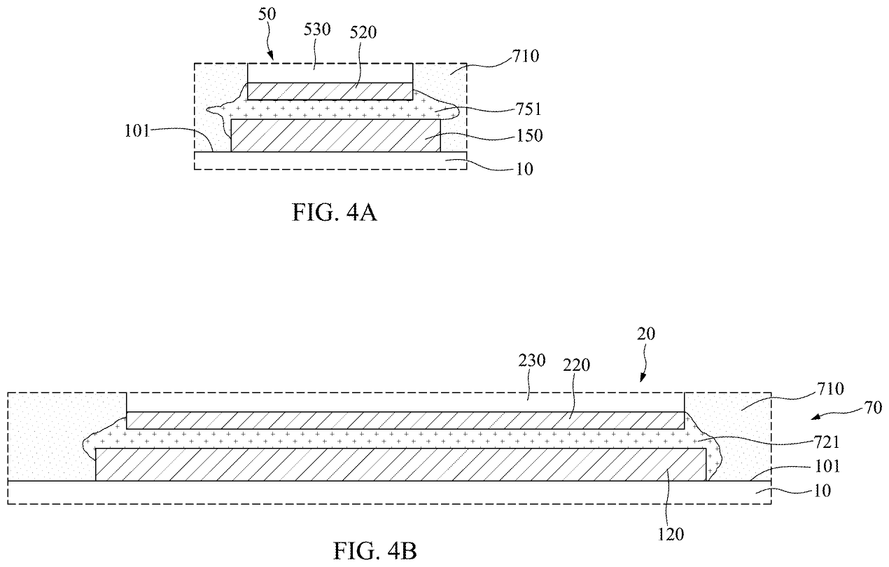

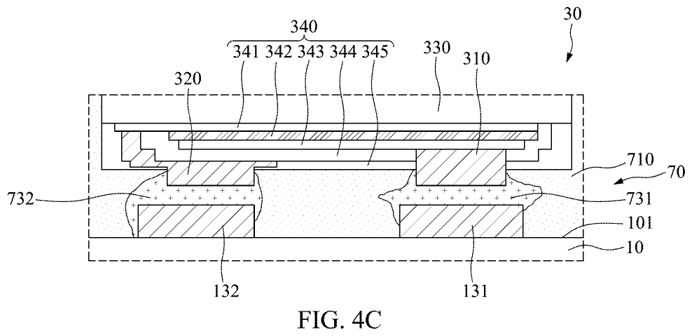

FIG. 4A is a cross-section of a portion of a package structure 3 in accordance with some arrangements of the present disclosure. In some arrangements, FIG. 4A is a cross-section of a portion 4A in FIG. 3.

In some arrangements, the conductive portion 751 covers or directly contacts the top surface of one or more portions of lateral surfaces of the conductive pad 150. In some arrangements, the conductive portion 751 may extend or protrude beyond one or more lateral surfaces (e.g., the surface 503 and 504) of the interposer 50. In some arrangements, the conductive portion 751 may extend or protrude beyond one or more lateral surfaces of the conductive pad 150. In some arrangements, the conductive portion 751 may extend or protrude beyond one or more lateral surfaces of the conductive pad 520.

FIG. 4B is a cross-section of a portion of a package structure 3 in accordance with some arrangements of the present disclosure. In some arrangements, FIG. 4B is a cross-section of a portion 4B in FIG. 3.

In some arrangements, the conductive portion 721 covers or directly contacts the top surface of one or more portions of lateral surfaces of the conductive pad 120. In some arrangements, the conductive portion 721 may extend or protrude beyond one or more lateral surfaces of the conductive pad 120. In some arrangements, the conductive portion 721 may extend or protrude beyond one or more lateral surfaces of the terminal 220.

FIG. 4C is a cross-section of a portion of a package structure 3 in accordance with some arrangements of the present disclosure. In some arrangements, FIG. 4C is a cross-section of a portion 4C in FIG. 3.

In some arrangements, the conductive portion 731 covers or directly contacts the top surface of one or more portions of lateral surfaces of the conductive pad 131 of the substrate 10. In some arrangements, the conductive portion 732 covers or directly contacts the top surface of one or more portions of lateral surfaces of the conductive pad 132 of the substrate 10. In some arrangements, the conductive portion 731 may extend or protrude beyond one or more lateral surfaces of the conductive pad 131. In some arrangements, the conductive portion 732 may extend or protrude beyond one or more lateral surfaces of the conductive pad 132.

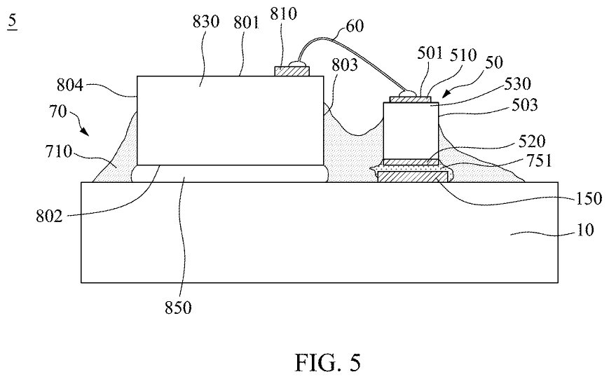

FIG. 5 is a cross-section of a package structure 5 in accordance with some arrangements of the present disclosure. The package structure 5 is similar to the package structure 1 illustrated in FIGS. 1A-1B, with differences therebetween as follows.

In some arrangements, the package structure 5 includes a substrate 10, an interposer 50, a conductive wire 60, a conductive adhesive 70, and an electronic component 80. In some arrangements, the electronic component 80 includes a conductive pad 810 and a substrate 830. The electronic component 80 may have a top surface 801, a bottom surface 802, and lateral surfaces 803 and 804.

In some arrangements, the bottom surface 802 of the electronic component 80 is adhered to the substrate 10 through an adhesive layer 850 (e.g., a die attached film (DAF). In some arrangements, the electronic component 80 is electrically connected to the substrate 10 through the conductive wire 60 and the interposer 50. In some arrangements, the conductive adhesive 70 includes a resin structure 710 partially covering the electronic component 80. In some arrangements, the resin structure 710 contacts the lateral surfaces 803 and 804 of the electronic component 80 and the adhesive layer 850. The electronic component 80 may include a processing component, e.g., an ASIC die.

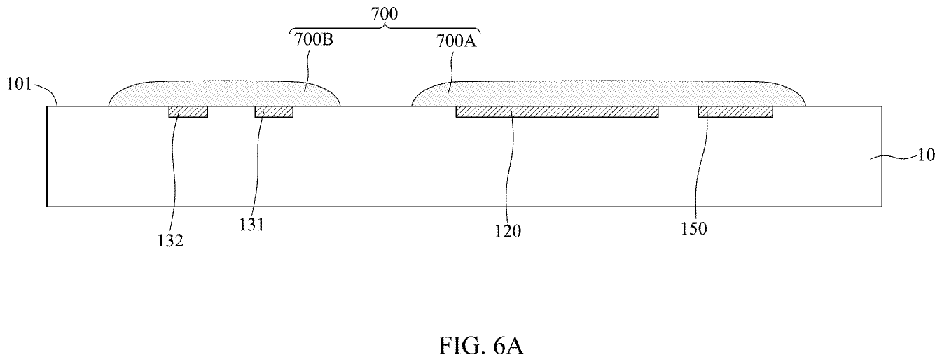

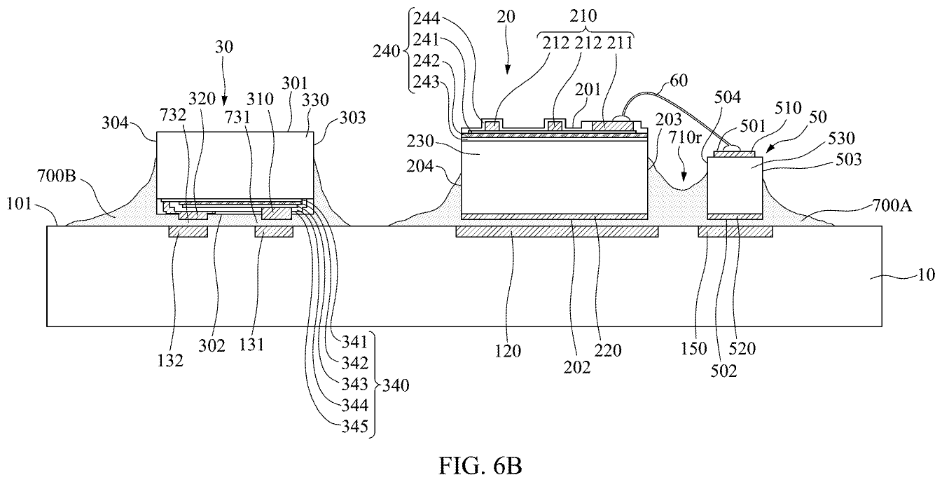

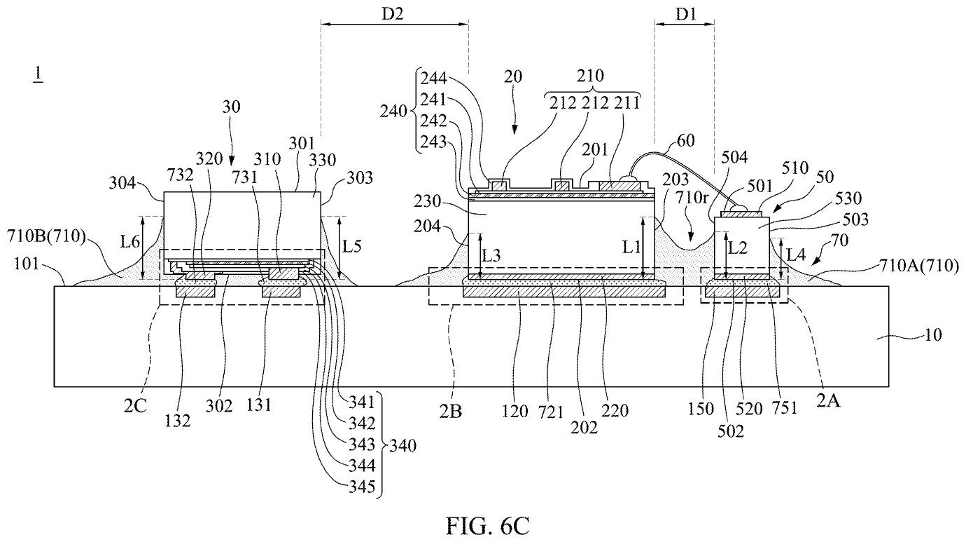

FIG. 6A, FIG. 6B, and FIG. 6C illustrate various stages of an exemplary method for manufacturing a package structure 1 in accordance with some arrangements of the present disclosure.

Referring to FIG. 6A, a substrate 10 including conductive pads 120, 131, 132, and 150 may be provided, and a conductive adhesive material 700 may be applied over a surface 101 of the substrate 10. In some arrangements, the conductive adhesive material 700 may be applied to cover the conductive pads 120, 131, 132, and 150. The conductive adhesive material 700 may include a plurality of portions (e.g., portions 700A and 700B) spaced apart from one another. Each of the portions may cover at least one of the conductive pads of the substrate 10. For example, the portion 700A covers the conductive pads 120 and 150, and the portion 700B covers the conductive pads 131 and 132. The conductive adhesive material 700 may include a resin material and conductive particles dispersed in the resin material. The conductive adhesive material 700 may be applied by dispensing, printing, or the like.

Referring to FIG. 6B, electronic components 20 and 30 and the interposer 50 may be disposed on and partially inserted into the conductive adhesive material 700. In some arrangements, the conductive adhesive material 700 is or includes a gel-type structure, such that the electronic components 20 and 30 and the interposer 50 are partially inserted into the conductive adhesive material 700 and maintain at predetermined positions within the conductive adhesive material 700. In some arrangements, bottom surfaces (e.g., the surfaces 202, 302, and 502) of the electronic components 20 and 30 and the interposer 50 are spaced apart from the conductive pads of the substrate 10 by one or more predetermined distances.

In some cases where electronic components are bonded to a substrate through solders, the solders may melt and become flowable upon heating during manufacture, thereby the relative position of the electronic components and the substrate may change unintentionally, and the shifted positions of the electronic components and the substrate may cause various problems, such as failure of the device, decreases in properties of the device, a decrease in the yield, and etc. According to some arrangements of the present disclosure, the electronic components and the interposers are connected to the conductive pads of the substrate through conductive portions of the conductive adhesive. Since the conductive adhesive material may include a gel-like structure that can fix the relative position between the electronic component 20, the interposer 50, and the substrate 10, such that undesired shifts in positions does not occur after subsequent thermal treatments, and a relatively satisfactory placement accuracy of the components can be achieved. Therefore, the electrical performance of the package structure 1 can be improved, and the yield can be improved as well.

In some arrangements, electronic components 20, 30, and 40 may be inserted into the conductive adhesive material 700 and arranged in an array as illustrated in FIG. 1A, and the interposers 50 may be interposed between the electronic components 20, 30, and 40.

Referring to FIG. 6C, a curing operation may be performed on the conductive adhesive material 700 to form an conductive adhesive 70 including conductive portions 721, 731, 732, and 751 and a resin structure 710 covering the conductive portions 721, 731, 732, and 751. The curing operation may be performed under a temperature from about 150° C. to about 170° C. After the curing operation is completed, the resin structure 710 is solidified and thus can fix the relative position between the electronic component 20, the interposer 50, and the substrate 10, and then a conductive wire 60 may be formed to electrically connect the electronic component 20 to the interposer 50. In some arrangements, the wire-bond operation is later than curing the conductive adhesive material 700. As such, the package structure 1 is formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate;
a first electronic component disposed over the substrate;
an interposer disposed over the substrate;
a conductive wire connecting the first electronic component to the interposer; and
a conductive adhesive connecting the interposer to the substrate.

2. The package structure as claimed in claim 1, wherein the conductive adhesive partially covers the interposer.

3. The package structure as claimed in claim 2, wherein the interposer comprises a first conductive pad connected to the conductive wire and at least partially exposed by the conductive adhesive.

4. The package structure as claimed in claim 3, wherein a height of the first electronic component is greater than a height of the interposer.

5. The package structure as claimed in claim 1, wherein the conductive adhesive comprises an anisotropic conductive adhesive.

6. The package structure as claimed in claim 1, wherein the conductive adhesive extends continuously from a lateral sidewall of the first electronic component to a lateral sidewall of the interposer in a cross-sectional view perspective.

7. The package structure as claimed in claim 6, wherein an elevation of a contact between the conductive wire and the first electronic component is higher than an elevation of a contact between the conductive wire and the interposer with respect to the substrate.

8. The package structure as claimed in claim 1, further comprising a second electronic component disposed over the substrate and flip-chip bonded to the substrate through the conductive adhesive.

9. A package structure, comprising:
a substrate;
a first electronic component disposed over the substrate, the first electronic component having a first surface facing the substrate and a second surface opposite to the first surface;
a second electronic component disposed over the substrate, the second electronic component having a third surface facing the substrate and comprising a first electrode on the third surface;
a conductive wire electrically connecting the second surface to the substrate;
a first conductive adhesive connecting the first surface to the substrate; and
a second conductive adhesive connecting the first electrode on the third surface to the substrate.

10. The package structure as claimed in claim 9, further comprising an interposer electrically connecting the conductive wire to the substrate.

11. The package structure as claimed in claim 10, wherein the first conductive adhesive is between the interposer and the substrate and connected to the interposer and the substrate.

12. The package structure as claimed in claim 11, wherein the interposer has a lateral surface, the first conductive adhesive comprises an insulating structure and a conductive portion, and the conductive portion is protruded beyond the lateral surface of the interposer.

13. The package structure as claimed in claim 9, wherein the second electronic component further comprises a second electrode connected to the substrate through the second conductive adhesive.

14. The package structure as claimed in claim 9, wherein the first electronic component comprises an electrode on the first surface, and the electrode is connected to the substrate through the first conductive adhesive.

15. The package structure as claimed in claim 9, wherein the first conductive adhesive is spaced apart from the second conductive adhesive.

16. A package structure, comprising:
a substrate;
a light-emitting array disposed over the substrate, the light-emitting array comprising a plurality of first light-emitting elements flip-chip bonded to the substrate and a plurality of second light-emitting elements wire-bonded to the substrate; and
a plurality of interposers disposed over the substrate, wherein the second light-emitting elements are wire-bonded to the substrate through the interposers.

17. The package structure as claimed in claim 16, wherein an elevation of a first light-emitting source of one of the first light-emitting elements is lower than an elevation of a second light-emitting source of one of the second light-emitting elements with respect to the substrate.

18. The package structure as claimed in claim 17, wherein the one of the first light-emitting elements comprises two electrodes on a same side of the first light-emitting source, and the one of the second light-emitting elements comprises two electrodes on opposite sides of the second light-emitting source.

19. The package structure as claimed in claim 16, wherein one of the first light-emitting elements and one of the second light-emitting elements are adjacent to each other, and one of the interposers connected to the one of the second light-emitting elements is disposed between the one of the first light-emitting elements and the one of the second light-emitting elements from a top view perspective.

20. The package structure as claimed in claim 19, wherein the one of the second light-emitting elements is closer to the one of the interposers than to the one of the first light-emitting elements.
